(19) United States
(12) Patent Application Publication
(10) Pub. No.: US 2026/0101750 A1
(43) Pub. Date: Apr. 9, 2026

(54) SEMICONDUCTOR DEVICE AND VEHICLE

(71) Applicant: Rohm Co., Ltd., Kyoto-shi (JP)

(72) Inventors: Masashi HAYASHIGUCHI, Kyoto-shi (JP); Hidetoshi ABE, Kyoto-shi (JP); Yoshihisa TSUKAMOTO, Kyoto-shi (JP)

(21) Appl. No.: 19/405,975

(22) Filed: Dec. 2, 2025

Related U.S. Application Data
(63) Continuation of application No. PCT/JP2024/017938, filed on May 15, 2024.

(30) Foreign Application Priority Data
Jun. 9, 2023 (JP) 2023-095550

(51) Int. Cl. H10W 40/47; H10W 70/40

(52) U.S. Cl. CPC H10W 40/47; H10W 70/429

(57) ABSTRACT

A semiconductor device includes a semiconductor element, and a first terminal that is positioned on a first side in a first direction from the semiconductor element and electrically connected to the semiconductor element. In the first direction, a first channel is provided between the semiconductor element and the first terminal. The semiconductor element is in contact with the first channel. In one example, the semiconductor device additionally includes a first conductive member that is electrically connected to the semiconductor element and the first terminal. The first conductive member is contained in the first channel.

### TECHNICAL FIELD

The present disclosure relates to a semiconductor device and a vehicle equipped with the semiconductor device.

### BACKGROUND ART

WO 2017/094370 discloses an example of a semiconductor module that is equipped with a semiconductor device and a cooling unit. The cooling unit includes a housing having a hollow interior and a heat sink. The housing is formed with an opening that leads into the hollow interior. The heat sink is attached to the housing to cover the opening. A portion of the heat sink extends into the hollow interior. The semiconductor device is bonded to the portion of the heat sink that falls outside the hollow interior. Coolant (such as cooling water) that flows through the hollow interior comes into contact with the heat sink. The heat sink thus efficiently cools the semiconductor device.

However, the semiconductor module of WO 2017/094370 is not configured to provide sufficient cooling for the semiconductor device, given the size of the cooling unit.

### BRIEF DESCRIPTION OF THE DRAWINGS

FIG. 1 is a plan view of a semiconductor device according to a first embodiment of the present disclosure.

FIG. 2 is a plan view corresponding to FIG. 1, in which the housing is shown as transparent.

FIG. 3 is a plan view corresponding to FIG. 2,, in which the first terminal is also shown as transparent.

FIG. 4 is a bottom view of the semiconductor device shown in FIG. 1.

FIG. 5 is a right-side view of the semiconductor device shown in FIG. 1.

FIG. 6 is a left-side view of the semiconductor device shown in FIG. 1.

FIG. 7 is a sectional view taken along line VII-VII in FIG. 3.

FIG. 8 is a sectional view taken along line VIII-VIII in FIG. 3.

FIG. 9 is a sectional view taken along line IX-IX in FIG. 3.

FIG. 10 is a partially enlarged view of FIG. 7.

FIG. 11 is a partially enlarged view of FIG. 8.

FIG. 12 is a sectional view for illustrating effects of the semiconductor device shown in FIG. 1.

FIG. 13 is a sectional view of a semiconductor device according to a second embodiment of the present disclosure, taken along a line that corresponds to the section shown in FIG. 7.

FIG. 14 is a sectional view of the semiconductor device shown in FIG. 13, taken along a line that corresponds to the section shown in FIG. 8.

FIG. 15 is a partially enlarged view of FIG. 13.

FIG. 16 is a sectional view of a semiconductor device according to a third embodiment of the present disclosure, taken along a line that corresponds to the section shown in FIG. 7.

FIG. 17 is a sectional view of the semiconductor device shown in FIG. 16, taken along a line that corresponds to the section shown in FIG. 8.

FIG. 18 is a partially enlarged view of FIG. 16.

FIG. 19 is a plan view of a semiconductor device according to a fourth embodiment of the present disclosure.

FIG. 20 is a bottom view of the semiconductor device shown in FIG. 19.

FIG. 21 is a sectional view taken along line XXI-XXI in FIG. 19.

FIG. 22 is a sectional view taken along line XXII-XXII in FIG. 19.

FIG. 23 is a plan view of a semiconductor device according to a fifth embodiment of the present disclosure, in which the housing is shown as transparent.

FIG. 24 is a sectional view taken along line XXIV-XXIV in FIG. 23.

FIG. 25 is a sectional view taken along line XXV-XXV in FIG. 23.

FIG. 26 is a sectional view taken along line XXVI-XXVI in FIG. 23.

FIG. 27 is a partially enlarged view of FIG. 24.

FIG. 28 is a partially enlarged view of FIG. 25.

FIG. 29 is a schematic view of a vehicle equipped with the semiconductor device shown in FIG. 23.

### DETAILED DESCRIPTION OF EMBODIMENTS

With reference to the accompanying drawings, the following describes modes for carrying out the present disclosure.

### First Embodiment

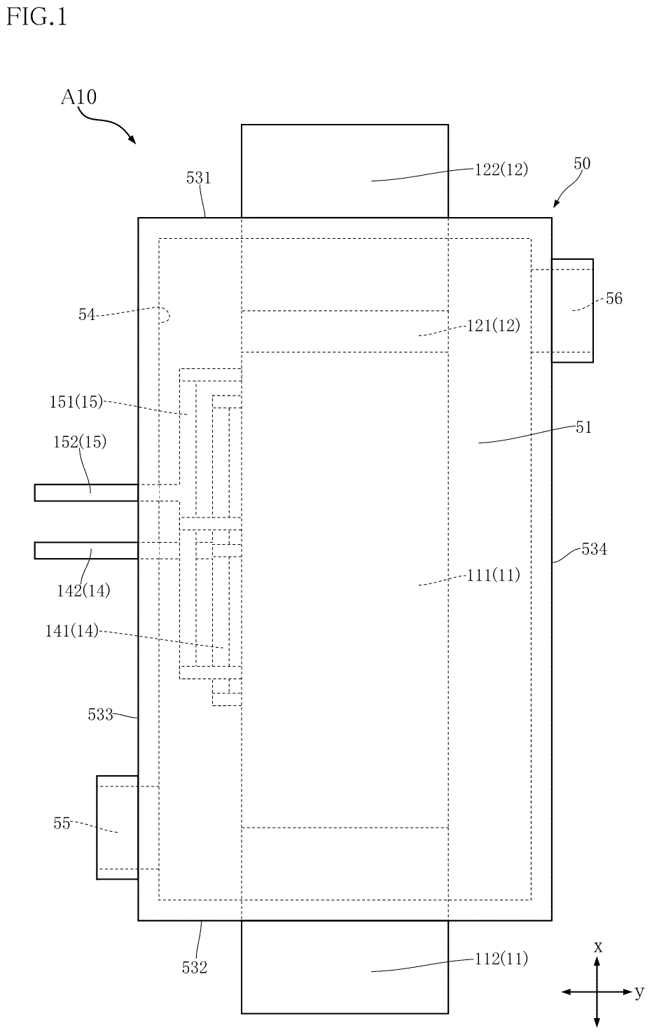

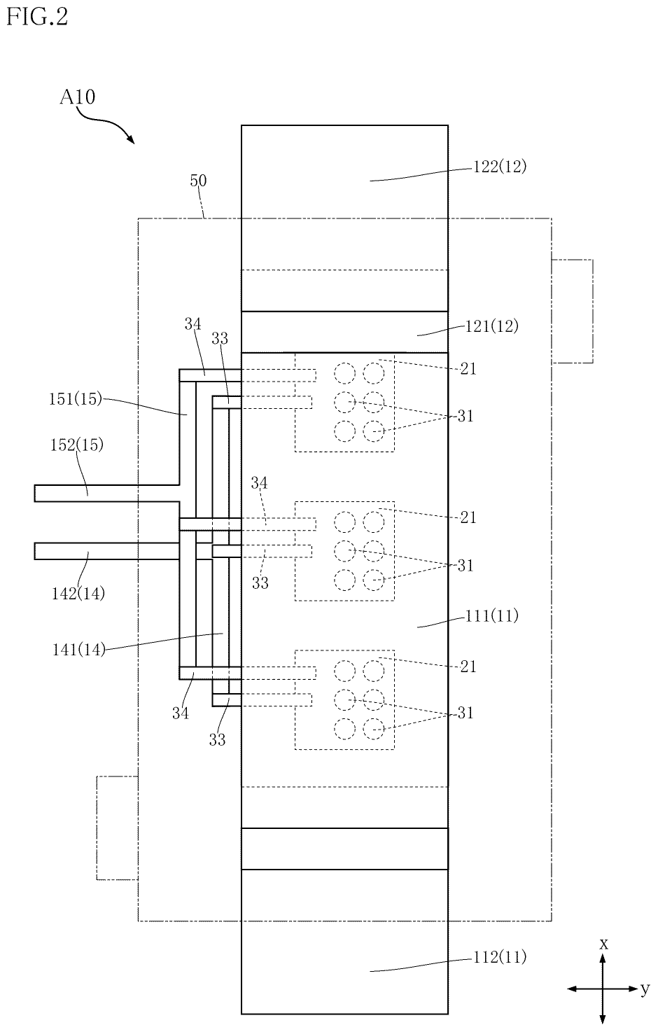

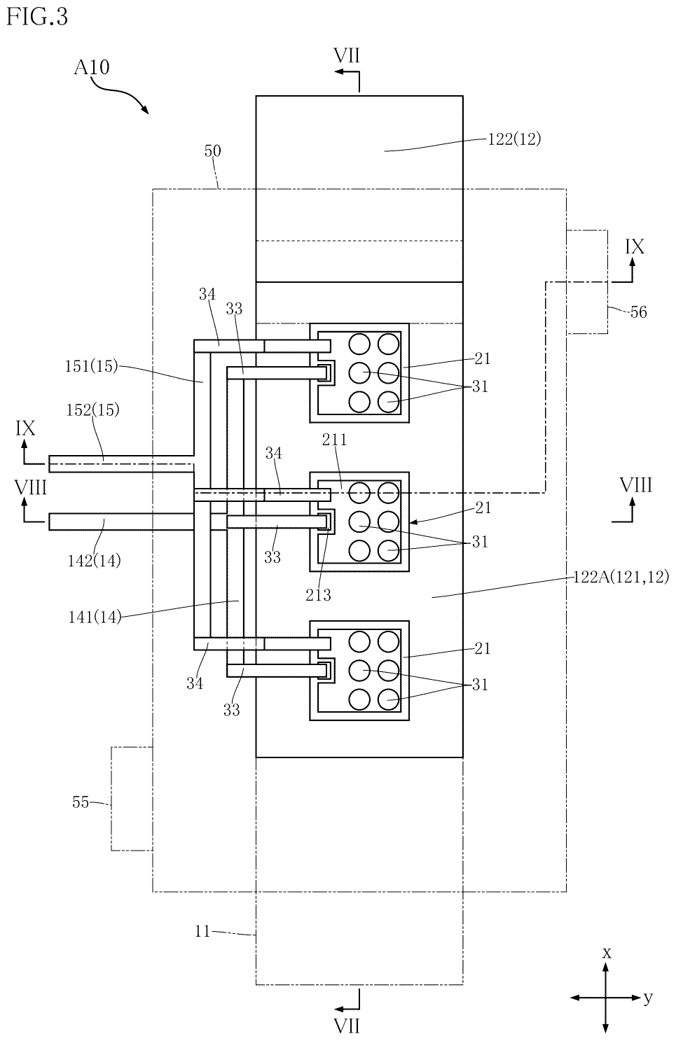

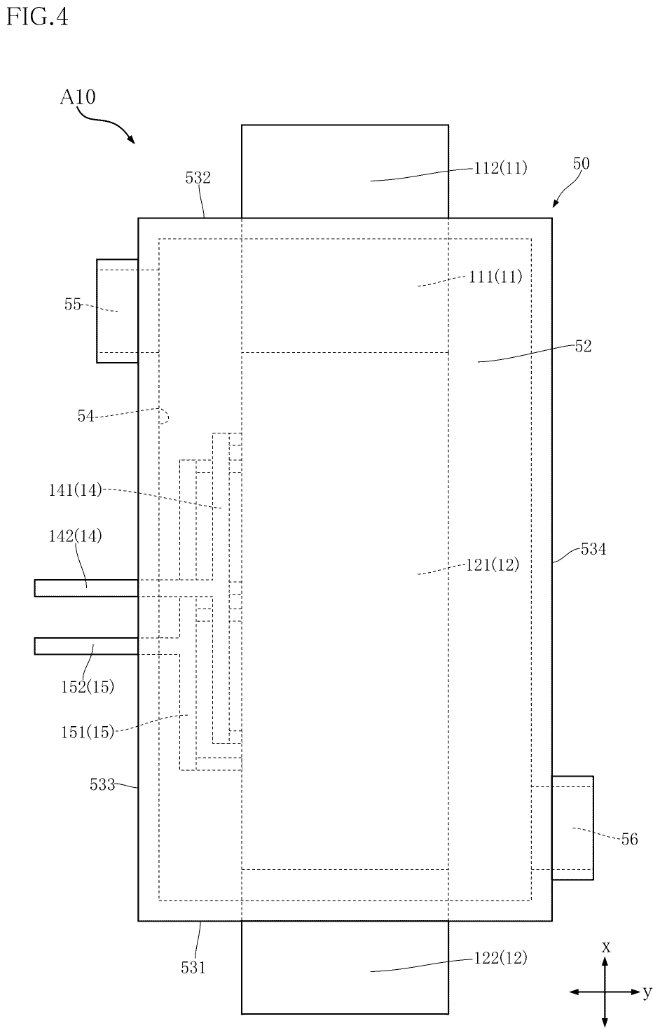

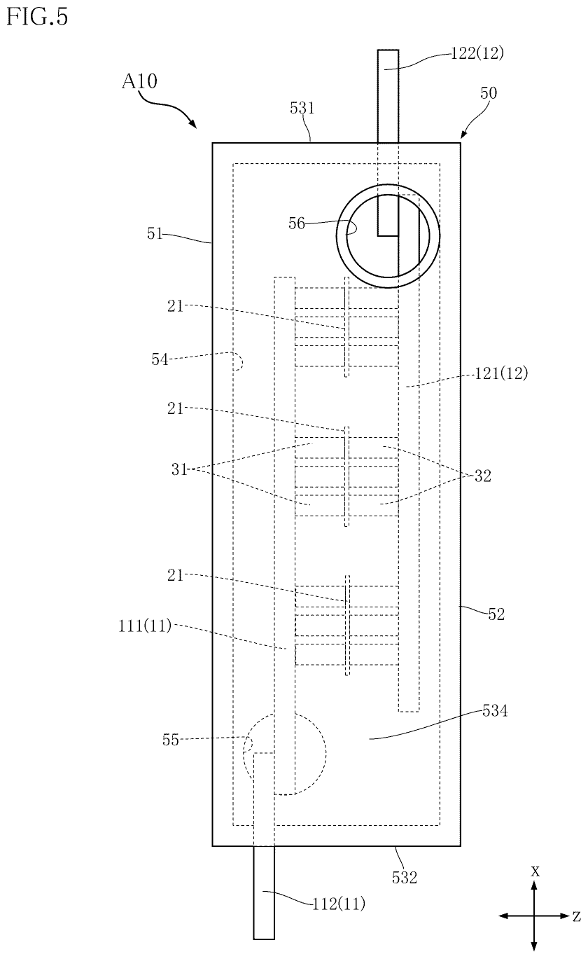

With reference to FIGS. 1 to 11, the following describes a semiconductor device A10 according to a first embodiment of the present disclosure. The semiconductor device A10 is typically used in a power conversion circuit, such as an inverter. The semiconductor device A10 includes a first terminal 11, a second terminal 12, a first signal terminal 14, a second signal terminal 15, a plurality of first semiconductor elements 21, a plurality of first conductive members 31, a plurality of second conductive members 32, a plurality of third conductive members 33, a plurality of fourth conductive members 34, and a housing 50. For ease of understanding, FIG. 2 shows the housing 50 as transparent. In FIG. 2, the outline of the housing 50 is shown in phantom lines (dash-double-dot lines). For ease of understanding, FIG. 3 shows the first terminal 11 and the housing 50 as transparent. In FIG. 3, the outlines of the first terminal 11 and housing 50 are shown in phantom lines (dash-double-dot lines).

For convenience in the description of the semiconductor device A10, the direction normal to the later-described first mounting surface 121A of the second terminal 12 is referred to as “first direction z.” A direction perpendicular to the first direction z is referred to as “second direction x. ” The direction perpendicular to both the first direction z and the second direction x is referred to as “third direction y.”

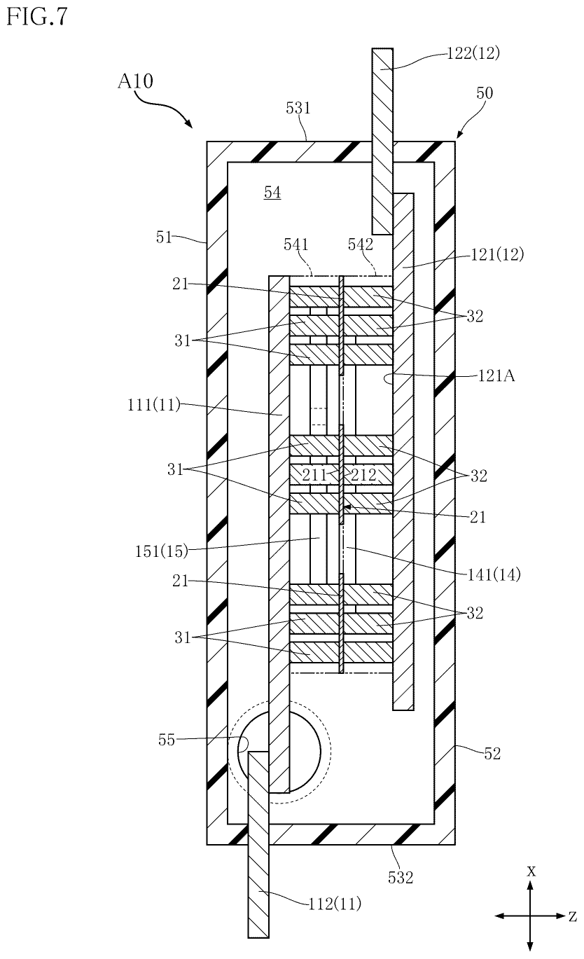

As shown in FIGS. 7 to 9, the housing 50 supports the first terminal 11, the second terminal 12, the first signal terminal 14, and the second signal terminal 15. The housing 50 is made of an insulating material, including resin. Alternatively, the housing 50 may be made of a conductive material, including metal, such as aluminum (Al).

As shown in FIGS. 1, 4, 5, and 6, the housing 50 has a top surface 51, a bottom surface 52, a first side surface 531, a second side surface 532, a third side surface 533, and a fourth side surface 534. The top surface 51 faces a first side in the first direction z. The bottom surface 52 faces away from the top surface 51 in the first direction z. The first side surface 531 and the second side surface 532 face away from each other in the second direction x. The third side surface 533 and the fourth side surface 534 face away from each other in the third direction y.

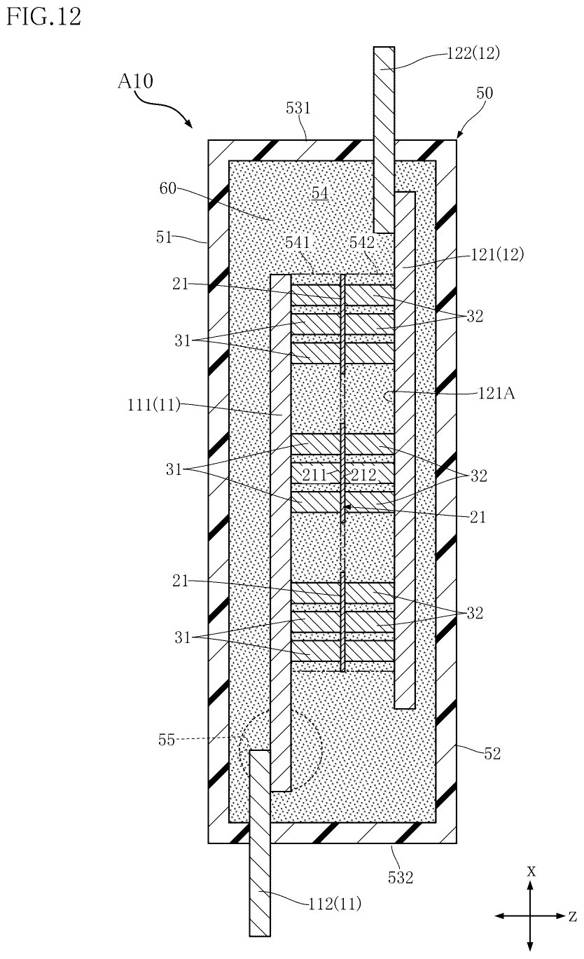

As shown in FIGS. 7 to 9, the housing 50 has a hollow space 54. The hollow space 54 is in communication with ambient air. Alternatively, as shown in FIG. 12, the hollow space 54 may be normally filled with a coolant 60. The hollow space 54 includes a first channel 541 and a second channel 542. The first channel 541 is provided between the plurality of first semiconductor elements 21 and the first terminal 11 in the first direction z. The second channel 542 is provided between the plurality of first semiconductor elements 21 and the second terminal 12 in the first direction z. Note that the coolant 60 shown FIG. 12 needs to be an insulator. In the present disclosure, the coolant 60 may have any composition as long as the coolant 60 is an insulator.

As shown in FIGS. 1, 4, 5, and 6, the housing 50 has an inlet 55 and an outlet 56. The inlet 55 is formed on the third side surface 533 and opens into the hollow space 54. The outlet 56 is formed on the fourth side surface 534 and opens into the hollow space 54. The coolant 60 shown in FIG. 12 enters the housing 50 through the inlet 55 and flows into the hollow space 54. Subsequently, the coolant 60 in the hollow space 54 exits through the outlet 56. As shown in FIG. 3, the inlet 55 and the outlet 56 are positioned opposite each other in the third direction y with respect to the first conductive members 31.

As shown in FIGS. 7 to 9, the first terminal 11 is positioned on the first side in the first direction z from the first semiconductor elements 21. In the semiconductor device A10, the first terminal 11 is positioned between the plurality of first semiconductor elements 21 and the top surface 51 of the housing 50 in the first direction z. The first terminal 11 is a metal plate containing copper (Cu), for example. The first terminal 11 has a first base 111 and a first extension 112. The first base 111 is contained in the hollow space 54 of the housing 50 and is in contact with the first channel 541. The first base 111 has a band-like shape extending in the second direction x. The first extension 112 is connected to the end of the first base 111 on a first side in the second direction x. The first extension 112 is supported by the housing 50. The first extension 112 has a portion protruding outward from the second side surface 532 of the housing 50.

As shown in FIGS. 7 to 9, the second terminal 12 is positioned opposite the first terminal 11 with respect to the plurality of first semiconductor elements 21 in the first direction z. In the semiconductor device A10, the second terminal 12 is positioned between the plurality of first semiconductor elements 21 and the bottom surface 52 of the housing 50 in the first direction z. The second terminal 12 is a metal plate containing copper, for example. The second terminal 12 has a second base 121 and a second extension 122. The second base 121 is contained in the hollow space 54 of the housing 50 and is in contact with the second channel 542. The second base 121 has a band-like shape extending in the second direction x. The second base 121 has a first mounting surface 121A that faces the same side as the top surface 51 of the housing 50 in the first direction z. The second extension 122 is electrically bonded to the end of the second base 121 on the first side in the second direction x. The second extension 122 is supported by the housing 50. The second extension 122 has a portion protruding outward from the first side surface 531 of the housing 50.

As shown in FIGS. 7 to 9, the first semiconductor elements 21 are positioned between the first base 111 of the first terminal 11 and the second base 121 of the second terminal 12 in the first direction z. The plurality of first semiconductor elements 21 are contained in the hollow space 54 of the housing 50. Each first semiconductor element 21 is in contact with both the first channel 541 and the second channel 542. As viewed in the first direction z, the first semiconductor elements 21 overlap the first mounting surface 121A of the second base 121. All of the first semiconductor elements 21 are identical. In one example, the first semiconductor elements 21 are MOSFETs (metal-oxide-semiconductor field-effect transistors). In other examples, the first semiconductor elements 21 may be field-effect transistors, including MISFETs (metal-insulator-semiconductor field-effect transistors), or bipolar transistors, including IGBTs (insulated gate bipolar transistors). In the description of the semiconductor device A10 below, the first semiconductor elements 21 are assumed to be n-channel, vertical MOSFETs. The first semiconductor elements 21 include a compound semiconductor substrate. The compound semiconductor substrate contains silicon carbide (SiC). The first semiconductor elements 21 are aligned in the second direction x.

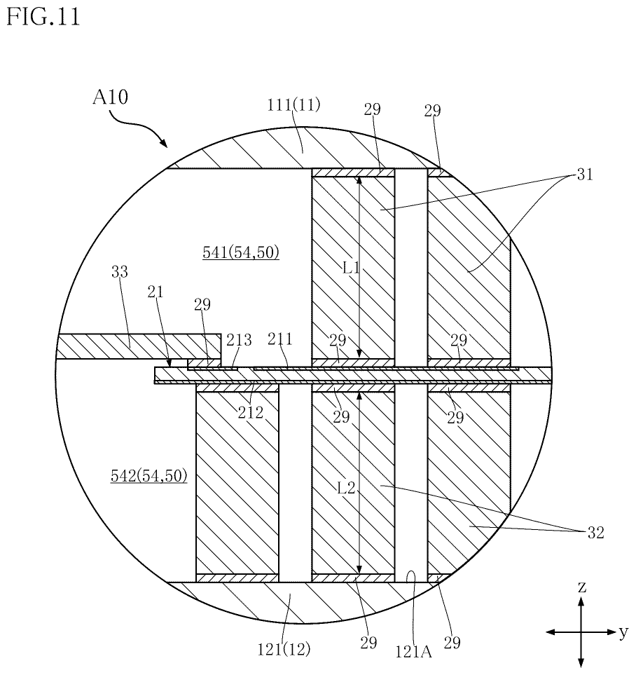

As shown in FIGS. 3 and 11, each first semiconductor element 21 includes a first electrode 211, a second electrode 212, and a first gate electrode 213.

As shown in FIG. 11, the first electrode 211 is disposed on the side that faces the first base 111 of the first terminal 11 in the first direction z. The first electrode 211 is electrically connected to the first terminal 11. The first electrode 211 carries the current corresponding to the power after conversion by the first semiconductor element 21. That is, the first electrode 211 corresponds to the source of the first semiconductor element 21. The first electrode 211 is in contact with the first channel 541.

As shown in FIG. 11, the second electrode 212 is disposed on the side that faces the second base 121 of the second terminal 12 in the first direction z. The second electrode 212 is electrically connected to the second terminal 12. The second electrode 212 carries the current corresponding to the power before conversion by the first semiconductor element 21. That is, the second electrode 212 corresponds to the drain of the first semiconductor element 21. The second electrode 212 is in contact with the second channel 542.

As shown in FIG. 11, the first gate electrode 213 is disposed on the same side as the first electrode 211 in the first direction z. The first gate electrode 213 is electrically connected to the first signal terminal 14. The first gate electrode 213 receives a gate voltage that drives the first semiconductor element 21. As shown in FIG. 3, the first gate electrode 213 has a smaller area than the first electrode 211 as viewed in the first direction z.

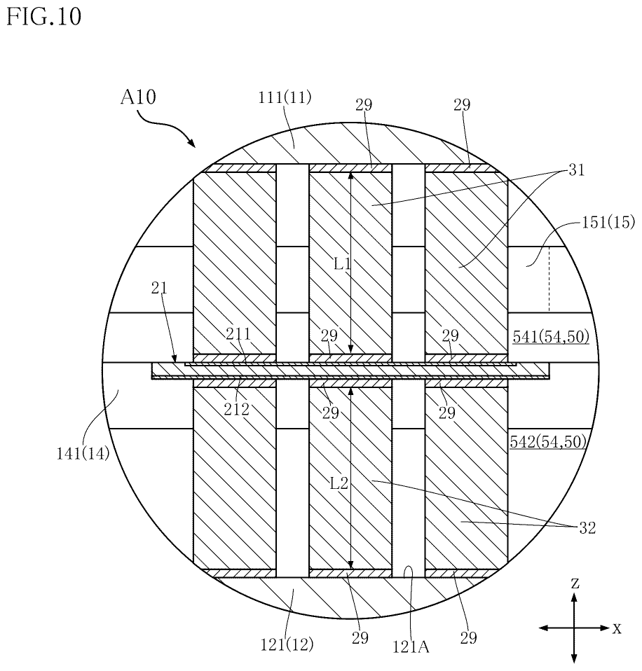

Each first conductive member 31 is electrically connected to the first electrode 211 of one of the first semiconductor elements 21 and to the first terminal 11. As shown in FIGS. 7 to 9, the first conductive members 31 are positioned between the plurality of first semiconductor elements 21 and the first base 111 of the first terminal 11 in the first direction z. The first conductive members 31 are contained in the first channel 541. The first conductive members 31 may be metal pieces containing copper, for example. Each first conductive member 31 may have a cylindrical shape. As shown in FIGS. 10 and 11, each first conductive member 31 is electrically connected at its end on the first side in the first direction z to the first electrode 211 of one of the first semiconductor elements 21 via a bonding layer 29. The bonding layer 29 is mad of is made of solder. In other examples, the bonding layer 29 may be made of a sintered metal that contains silver (Ag). Each first conductive member 31 is electrically connected at its end on a second side in the first direction z to the first base 111 of the first terminal 11 via a bonding layer 29. Each first conductive member 31 has a dimension L1 in the first direction z, where the dimension L1 is greater than a dimension of the first conductive member 31 in a direction perpendicular to the first direction z.

Each second conductive member 32 is electrically connected to the second electrode 212 of one of the first semiconductor elements 21 and to the second terminal 12. As shown in FIGS. 7 to 9, the second conductive members 32 are positioned between the plurality of first semiconductor elements 21 and the second base 121 of the second terminal 12 in the first direction z. The second conductive members 32 are contained in the second channel 542. The second conductive members 32 are metal pieces containing copper, for example. Each second conductive member 32 may have a cylindrical shape. As shown in FIGS. 10 and 11, each second conductive member 32 is electrically connected at its end on the first side in the first direction z to the second electrode 212 of one of the first semiconductor elements 21 via a bonding layer 29. Each second conductive member 32 is electrically connected at its end on the second side in the first direction z to the first mounting surface 121A of the second base 121 via a bonding layer 29. Each second conductive member 32 has a dimension L2 in the first direction z, where the dimension L2 is greater than a dimension of the second conductive member 32 in a direction perpendicular to the first direction z.

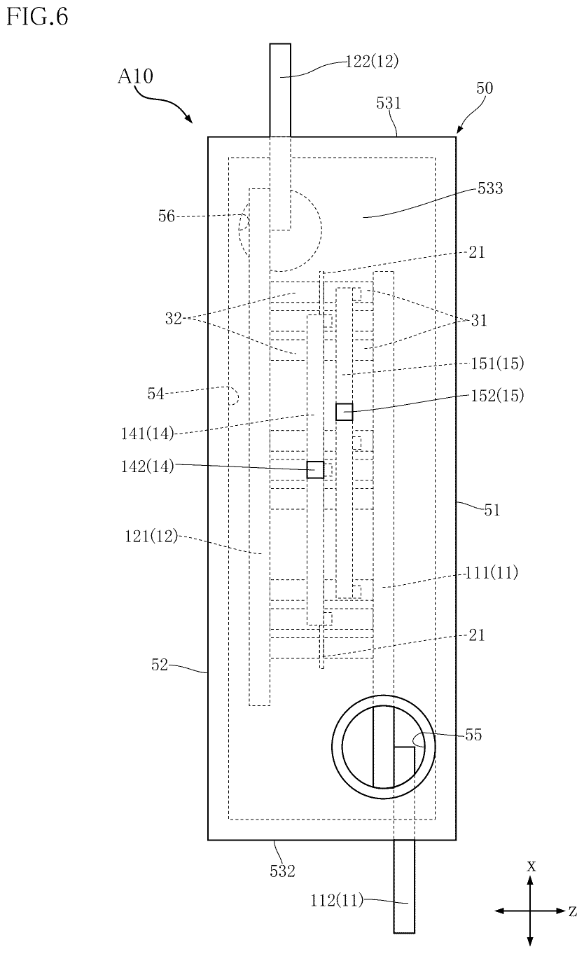

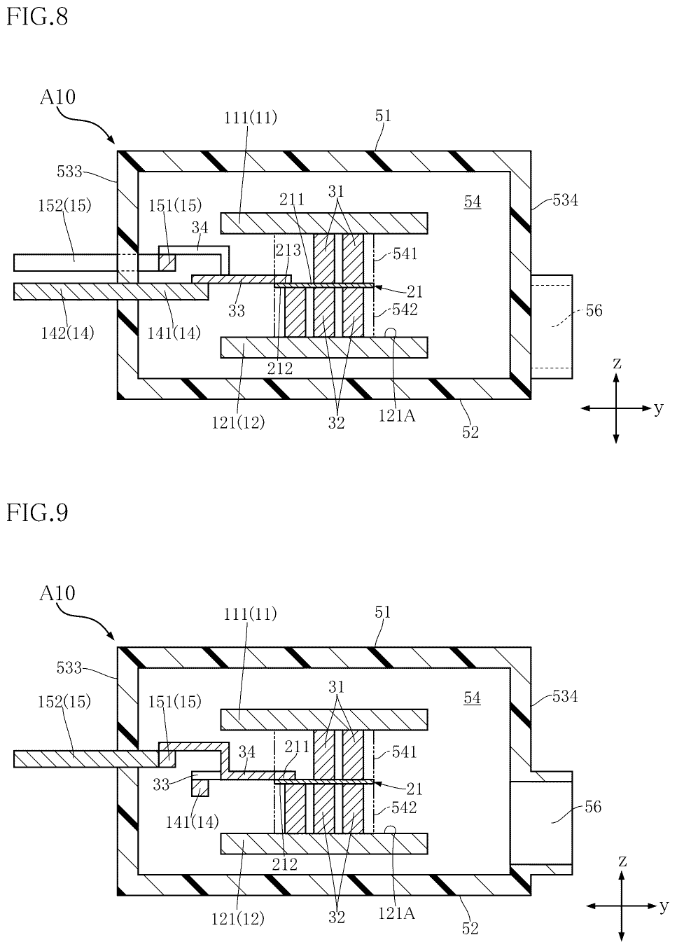

As shown in FIG. 2, the first signal terminal 14 is positioned on a first side in the third direction y from the first terminal 11. The first signal terminal 14 is supported by the housing 50. The first signal terminal 14 is electrically connected to the first gate electrode 213 of each first semiconductor element 21. The first signal terminal 14 receives a gate voltage that drives the first semiconductor elements 21. The first signal terminal 14 is a metal lead containing copper, for example. As shown in FIG. 3, the first signal terminal 14 includes an inner portion 141 and an outer portion 142. The inner portion 141 is contained in the housing 50. The inner portion 141 has a portion contained in the hollow space 54 of the housing 50. The inner portion 141 has a portion extending in the second direction x. The outer portion 142 is connected to the inner portion 141. As shown in FIGS. 6 and 8, the outer portion 142 protrudes outward from the third side surface 533 of the housing 50.

Each third conductive member 33 is electrically connected to the first gate electrode 213 of one of the first semiconductor elements 21 and to the first signal terminal 14. As shown in FIG. 3, each third conductive member 33 extends in the third direction y. Each third conductive member 33 has a portion contained in the first channel 541. The third conductive members 33 are metal leads containing copper, for example. Each third conductive member 33 is electrically connected at its end on a first side in the third direction y to the first gate electrode 213 of one of the first semiconductor elements 21 via a bonding layer 29. Each third conductive member 33 is electrically connected at its end on the second side in the third direction y to the inner portion 141 of the first signal terminal 14.

As shown in FIG. 2, the second signal terminal 15 is positioned on the same side as the first signal terminal 14 from the first terminal 11 in the third direction y. The second signal terminal 15 is supported by the housing 50. The second signal terminal 15 is electrically connected to the first electrode 211 of each first semiconductor element 21. The second signal terminal 15 receives a voltage that is equal to the voltage applied to the first electrode 211 of each first semiconductor element 21. The second signal terminal 15 is a metal lead containing copper, for example. As shown in FIG. 3, the second signal terminal 15 includes an inner portion 151 and an outer portion 152. The inner portion 151 is contained in the housing 50. The inner portion 151 has a portion contained in the hollow space 54 of the housing 50. The inner portion 151 has a portion extending in the second direction x. As shown in FIGS. 8 and 9, the inner portion 151 is positioned closer to the top surface 51 of the housing 50 than the inner portion 141 of the first signal terminal 14 is. The outer portion 152 is connected to the inner portion 151. As shown in FIGS. 6 and 9, the outer portion 152 protrudes outward from the third side surface 533 of the housing 50.

Each fourth conductive member 34 is electrically connected to the first electrode 211 of one of the first semiconductor elements 21 and to the second signal terminal 15. As shown in FIG. 3, each fourth conductive member 34 extends in the third direction y as viewed in the first direction z. As shown in FIG. 9, each fourth conductive member 34 spans over the inner portion 141 of the first signal terminal 14. Each fourth conductive member 34 has a portion contained in the first channel 541. The fourth conductive members 34 are metal leads containing copper, for example. Each fourth conductive member 34 is electrically connected at its end on the first side in the third direction y to the first electrode 211 of one of the first semiconductor elements 21. Each fourth conductive member 34 is electrically connected at its end on the second side in the third direction y to the inner portion 151 of the second signal terminal 15.

The following describes the effects of the semiconductor device A10.

The semiconductor device A10 includes a first semiconductor element 21 and a first terminal 11. The first terminal 11 is positioned on a first side in a first direction z from the first semiconductor element 21 and is electrically connected to the first terminal 11. A first channel 541 is provided between the first semiconductor element 21 and the first terminal 11 in the first direction z. The first semiconductor element 21 is in contact with the first channel 541. In this configuration, the coolant 60 that flows into the hollow space 54 of the housing 50 flows through the first channel 541 as shown in FIG. 12. This ensures that the coolant 60 directly contacts the first semiconductor element 21, so that the semiconductor device A10 achieves a higher cooling efficiency than the conventional configuration. That is, this configuration of the semiconductor device A10 can further improve the cooling efficiency.

The semiconductor device A10 also includes a first conductive member 31 electrically connected to the first semiconductor element 21 and the first terminal 11. The first conductive member 31 is contained in the first channel 541. This configuration ensures that the coolant 60 directly contacts the first conductive member 31. This allows the heat conducted from the first semiconductor element 21 to the first conductive member 31 to efficiently dissipate into the surroundings.

The first electrode 211 of the first semiconductor element 21 is in contact with the first channel 541. This configuration ensures that the coolant 60 directly contacts the first electrode 211. This allows the heat of the first semiconductor element 21 to efficiently dissipate into the surroundings.

The first conductive member 31 has a dimension L1 in the first direction z, where the dimension L1 is greater than a dimension of the first conductive member 31 in a direction perpendicular to the first direction z. This configuration reduces the energy loss of the coolant 60 as it flows through the first channel 541, despite the abrupt narrowing caused by the first conductive member 31.

The semiconductor device A10 also includes a second terminal 12 and a second conductive member 32. A second channel 542 is provided between the first semiconductor element 21 and the second terminal 12 in the first direction z. The second conductive member 32 is contained in the second channel 542. The first semiconductor element 21 is in contact with the second channel 542. In this configuration, the coolant 60 that flows into the hollow space 54 of the housing 50 flows through the first channel 541 and also through the second channel 542 as shown in FIG. 12. This ensures that a greater amount of coolant 60 directly contacts the first semiconductor element 21, so that the semiconductor device A10 achieves a higher cooling efficiency than the conventional configuration.

The second electrode 212 of the first semiconductor element 21 is in contact with the second channel 542. This configuration ensures that the coolant 60 directly contacts the second electrode 212. This allows the heat of the first semiconductor element 21 to more efficiently dissipate into the surroundings.

The second conductive member 32 has a dimension L2 in the first direction z, where the dimension L2 is greater than a dimension of the second conductive member 32 in a direction perpendicular to the first direction z. This configuration reduces the energy loss of the coolant 60 as it flows through the second channel 542, despite the abrupt narrowing caused by the second conductive member 32.

The semiconductor device A10 also includes a housing 50 that supports the first terminal 11 and the second terminal 12. The housing 50 has an inlet 55 and an outlet 56. The inlet 55 and the outlet 56 are positioned opposite each other in a direction perpendicular to the first direction z with respect to the first conductive members 31. This configuration facilitates the flow of the coolant 60 in direct contact with the first conductive member 31.

### Second Embodiment

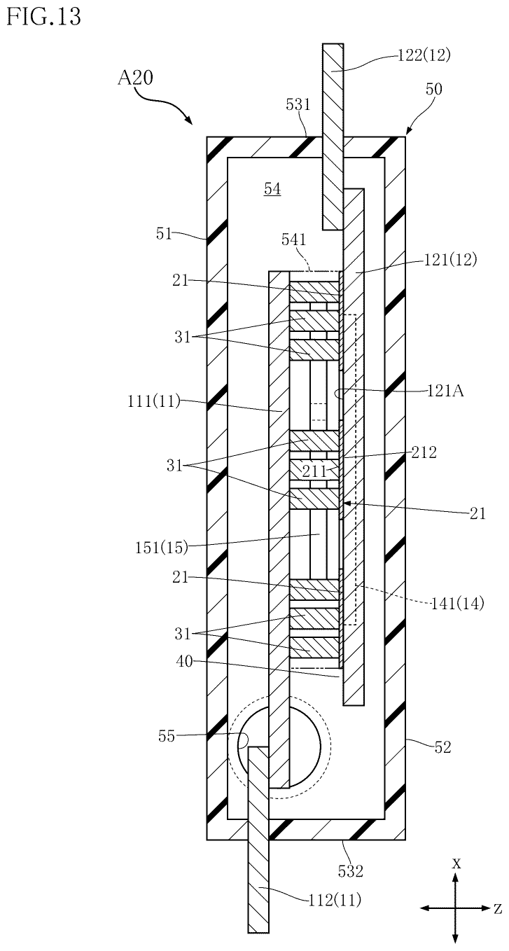

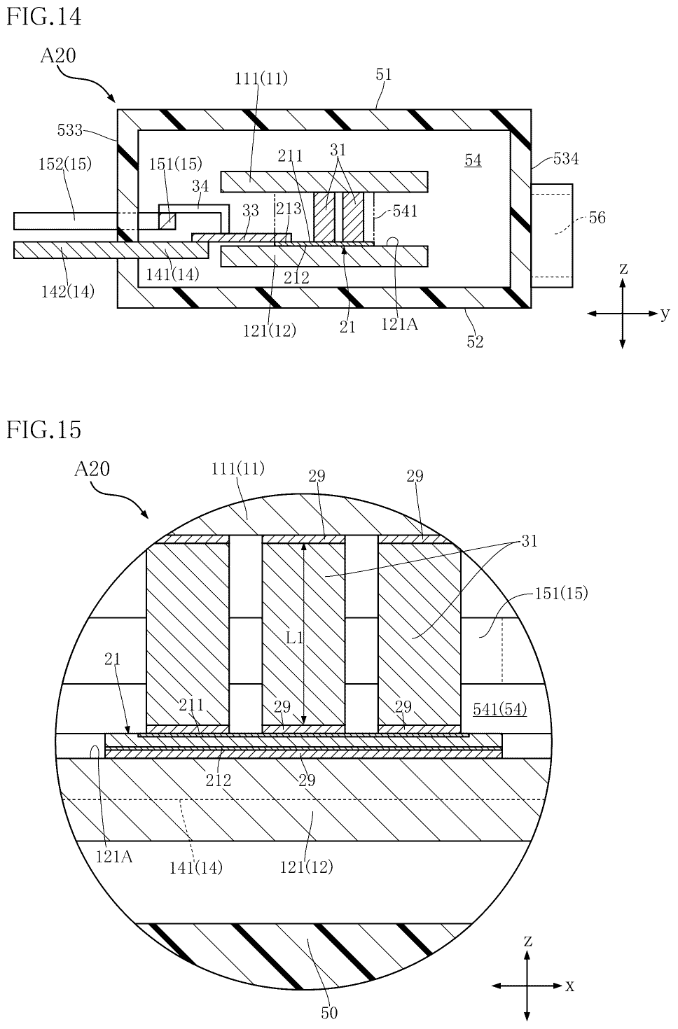

With reference to FIGS. 13 to 15, the following describes a semiconductor device A20 according to a second embodiment of the present disclosure. In these figures, elements that are identical or similar to those of the semiconductor device A10 are indicated by the same reference numerals, and overlapping descriptions are omitted. The section shown in FIG. 13 corresponds to the section of the semiconductor device A10 shown in FIG. 7. The section shown in FIG. 14 corresponds to the section of the semiconductor device A10 shown in FIG. 8.

Unlike the semiconductor device A10, the semiconductor device A20 includes no second conductive members 32.

As shown in FIGS. 13 to 15, the second electrode 212 of each first semiconductor element 21 is electrically bonded to the first mounting surface 121A of the second base 121 of the second terminal 12 via a bonding layer 29.

The following describes effects of the semiconductor device A20.

The semiconductor device A20 includes a first semiconductor element 21 and a first terminal 11. The first terminal 11 is positioned on a first side in a first direction z from the first semiconductor element 21 and is electrically connected to the first terminal 11. A first channel 541 is provided between the first semiconductor element 21 and the first terminal 11 in the first direction z. The first semiconductor element 21 is in contact with the first channel 541. That is, this configuration of the semiconductor device A20 can further improve the cooling efficiency. Additionally, the semiconductor device A20 has a configuration in common with the semiconductor device A10, thereby achieving the same effects as the semiconductor device A10.

In the semiconductor device A20, the second electrode 212 of the first semiconductor element 21 is electrically bonded to the second terminal 12. This configuration of the semiconductor device A20 eliminates the need for the second conductive members 32. This results in a shorter conductive path between the second electrode 212 and the second terminal 12, thereby reducing parasitic inductance in the semiconductor device A20.

### Third Embodiment

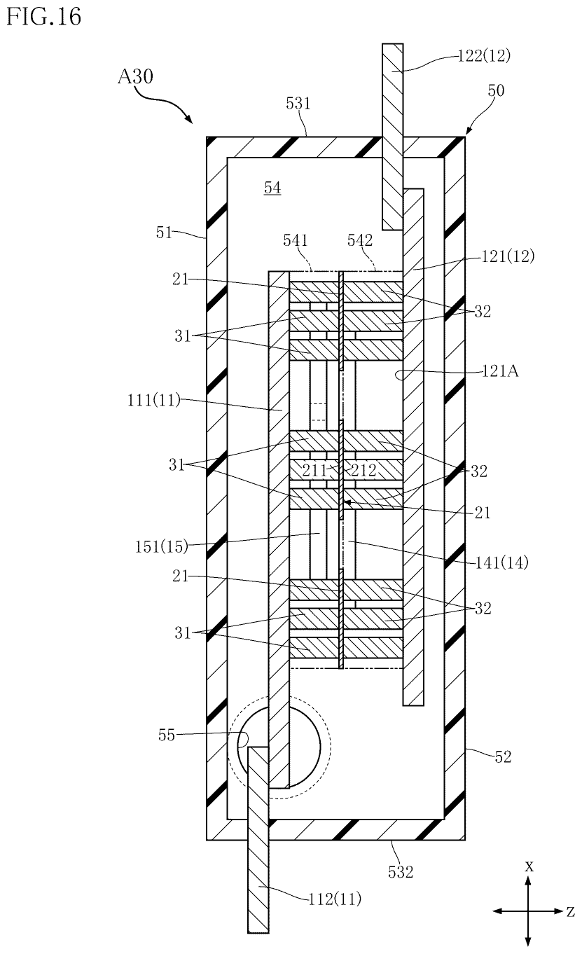

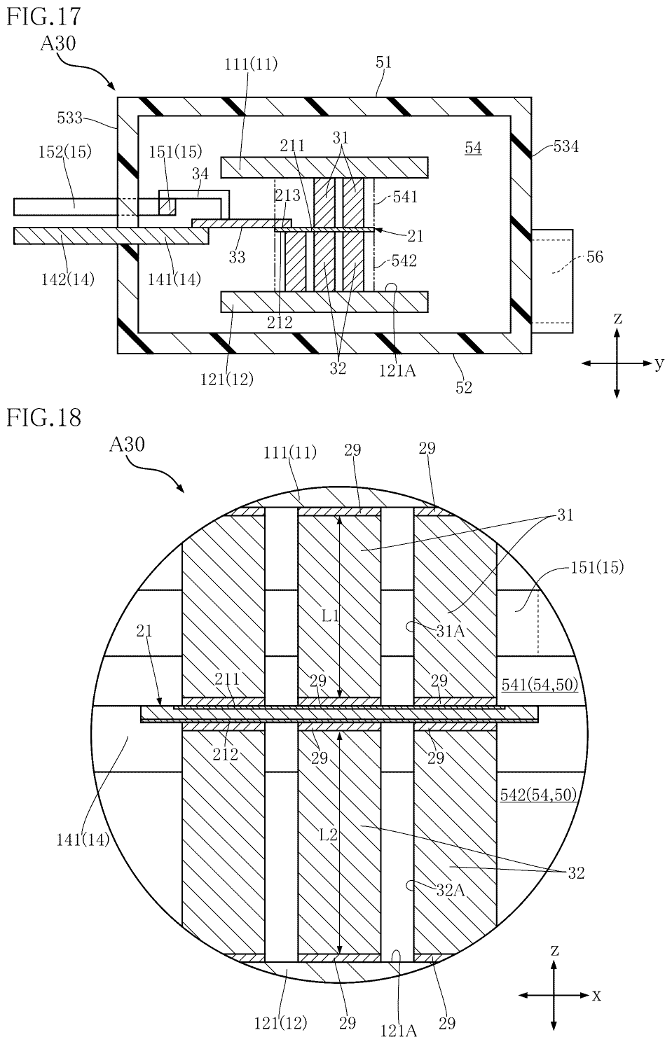

With reference to FIGS. 16 to 18, the following describes a semiconductor device A30 according to a third embodiment of the present disclosure. In these figures, elements that are identical or similar to those of the semiconductor device A10 are indicated by the same reference numerals, and overlapping descriptions are omitted. The section shown in FIG. 16 corresponds to the section of the semiconductor device A10 shown in FIG. 7. The section shown in FIG. 17 corresponds to the section of the semiconductor device A10 shown in FIG. 8.

The semiconductor device A30 differs from the semiconductor device A10 in the configurations of the first conductive members 31 and the second conductive members 32.

As shown in FIGS. 16 to 18, each second conductive member 32 has a dimension L2 in the first direction z, and the dimension L2 is greater than the dimension L1 of each first conductive member 31 in the first direction z. As shown in FIG. 18, each first conductive member 31 has a first peripheral surface 31A facing in a direction perpendicular to the first direction z. Each second conductive member 32 has a second peripheral surface 32A facing in a direction perpendicular to the first direction z. The second peripheral surface 32A has a larger area than the first peripheral surface 31A.

The following describes effects of the semiconductor device A30.

The semiconductor device A30 includes a first semiconductor element 21 and a first terminal 11. The first terminal 11 is positioned on a first side in a first direction z from the first semiconductor element 21 and is electrically connected to the first terminal 11. A first channel 541 is provided between the first semiconductor element 21 and the first terminal 11 in the first direction z. The first semiconductor element 21 is in contact with the first channel 541. This configuration of the semiconductor device A30 can further improve the cooling efficiency. Additionally, the semiconductor device A30 has a configuration in common with the semiconductor device A10, thereby achieving the same effects as the semiconductor device A10.

In the semiconductor device A30, each first conductive member 31 has a first peripheral surface 31A facing in a direction perpendicular to the first direction z. Each second conductive member 32 has a second peripheral surface 32A facing in a direction perpendicular to the first direction z. This configuration ensures, as shown in FIG. 12, that the second conductive member 32 will have a greater contact area with the coolant 60 than the first conductive member 31 when the coolant 60 flows into the hollow space 54 of the housing 50. This causes the first semiconductor element 21 to more easily dissipate the heat from the second electrode 212 into the surroundings than the heat from the first electrode 211.

### Fourth Embodiment

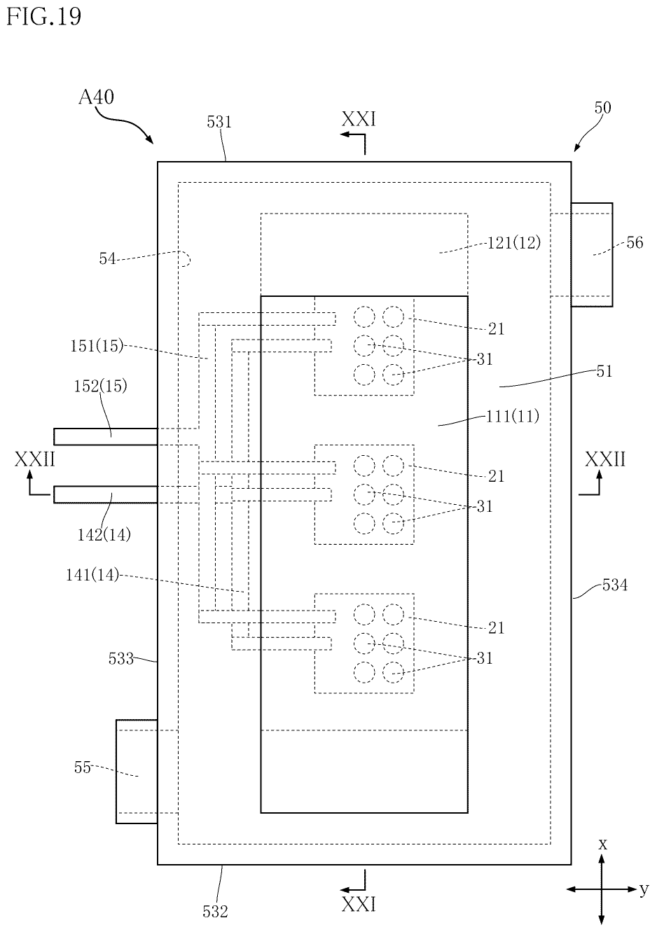

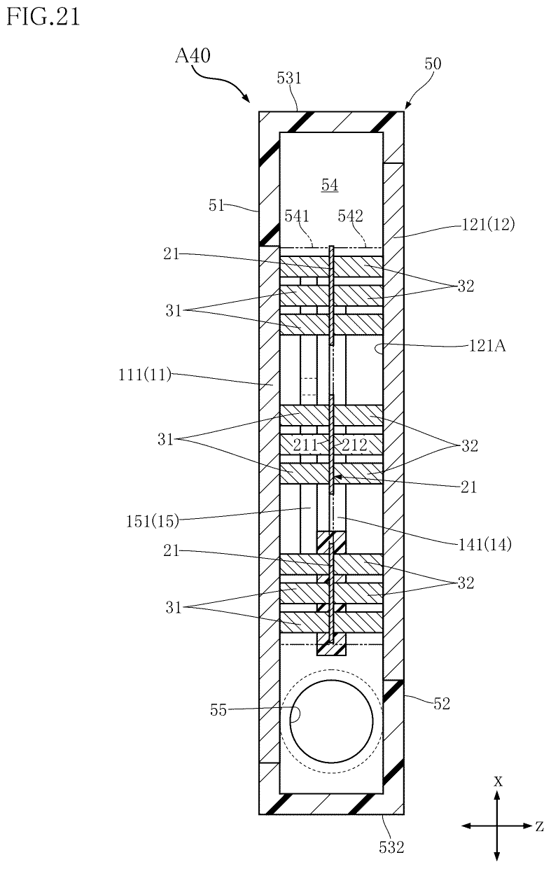

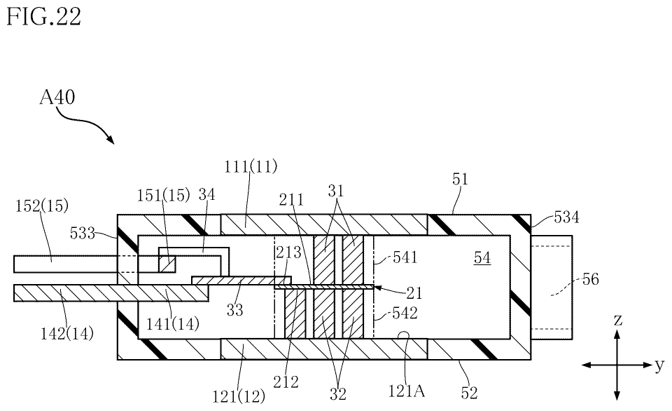

With reference to FIGS. 19 to 22, the following describes a semiconductor device A40 according to a fourth embodiment of the present disclosure. In these figures, elements that are identical or similar to those of the semiconductor device A10 are indicated by the same reference numerals, and overlapping descriptions are omitted.

The semiconductor device A40 differs from the semiconductor device A10 in the configurations of the first terminal 11 and the second terminal 12.

As shown in FIGS. 19, 21, and 22, the first terminal 11 has a first base 111 that is exposed to the outside at the top surface 51 of the housing 50. Unlike in the semiconductor device A10, the first terminal 11 does not have a first extension 112.

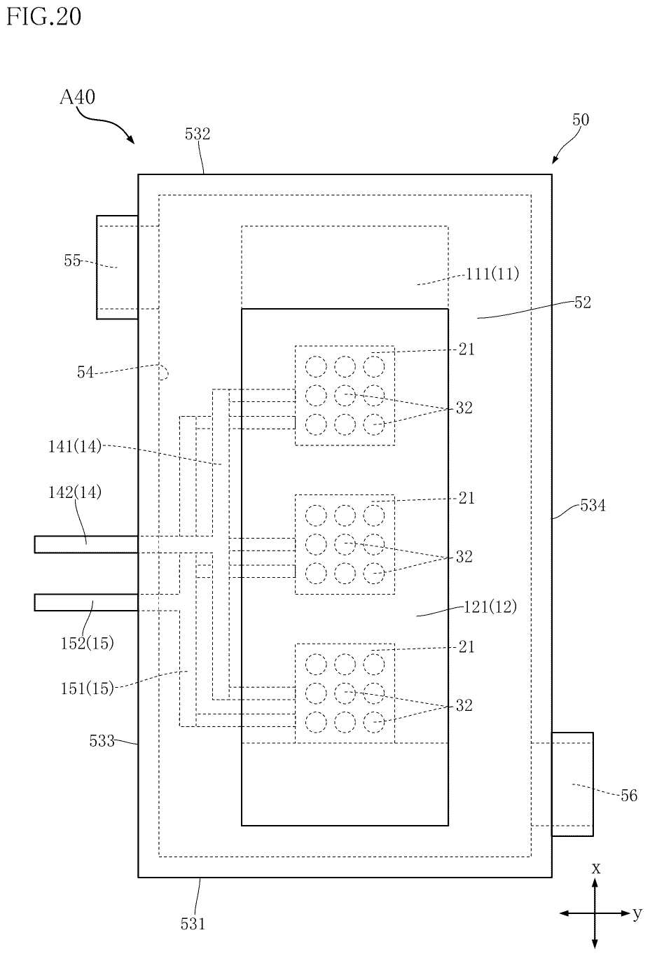

As shown in FIGS. 20 to 22, the second terminal 12 has a second base 121 that is exposed to the outside at the bottom surface 52 of the housing 50. Unlike in the semiconductor device A10, the second terminal 12 does not have a second extension 122.

The following describes effects of the semiconductor device A40.

The semiconductor device A40 includes a first semiconductor element 21 and a first terminal 11. The first terminal 11 is positioned on a first side in a first direction z from the first semiconductor element 21 and is electrically connected to the first terminal 11. A first channel 541 is provided between the first semiconductor element 21 and the first terminal 11 in the first direction z. The first semiconductor element 21 is in contact with the first channel 541. This configuration of the semiconductor device A40 can further improve the cooling efficiency. Additionally, the semiconductor device A40 has a configuration in common with the semiconductor device A10, thereby achieving the same effects as the semiconductor device A10.

In the semiconductor device A40, the first terminal 11 is exposed to the outside at the top surface 51 of the housing 50. The second terminal 12 is exposed to the outside at the bottom surface 52 of the housing 50. This configuration allows the semiconductor device A40 to have a reduced dimension in the first direction z.

### Fifth Embodiment

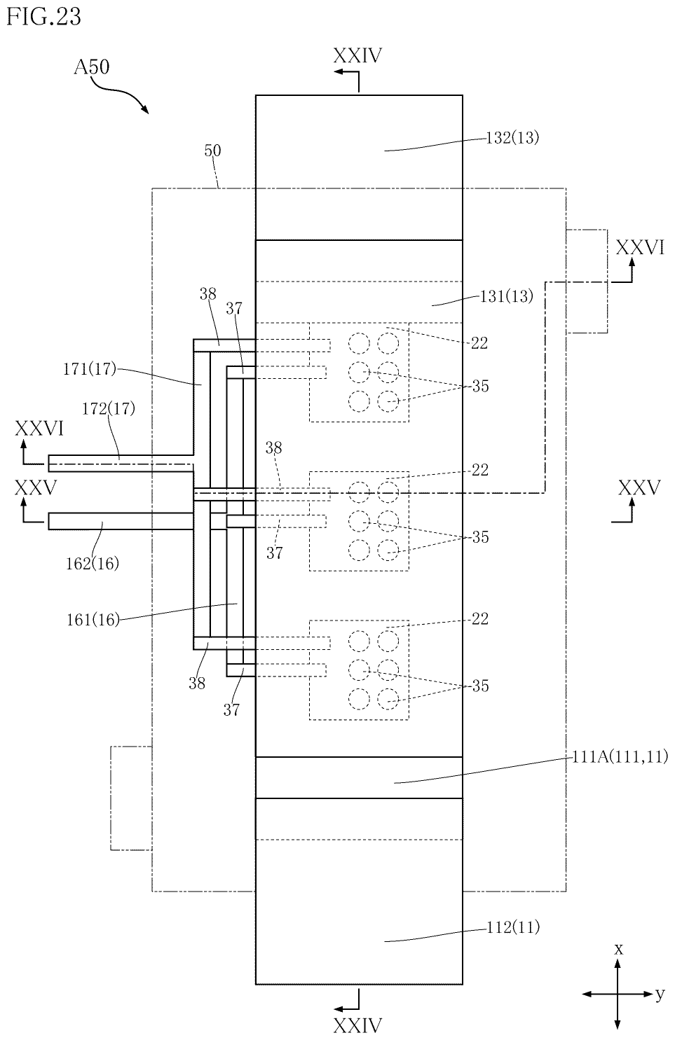

With reference to FIGS. 23 to 28, the following describes a semiconductor device A50 according to a fifth embodiment of the present disclosure. In these figures, elements that are identical or similar to those of the semiconductor device A10 are indicated by the same reference numerals, and overlapping descriptions are omitted. Note that FIG. 23 shows the housing 50 as transparent for ease of understanding. FIG. 23 shows the outline of the housing 50 in phantom lines.

The semiconductor device A50 includes the components and elements of the semiconductor device A10, and additionally includes a third terminal 13, a third signal terminal 16, a fourth signal terminal 17, a plurality of second semiconductor elements 22, a plurality of fifth conductive members 35, a plurality of sixth conductive members 36, a plurality of seventh conductive members 37, and a plurality of eighth conductive members 38.

In the semiconductor device A50, a half-bridge circuit is formed by the first semiconductor elements 21 and the second semiconductor elements 22. The semiconductor device A50 converts the DC power supplied to the second terminal 12 and the third terminal 13 into AC power via the first semiconductor elements 21 and the second semiconductor elements 22. The second terminal 12 is a P terminal (positive terminal), whereas the third terminal 13 is an N terminal (negative terminal). The AC power generated by the conversion is output from the first terminal 11 and supplied to a load, such as a motor.

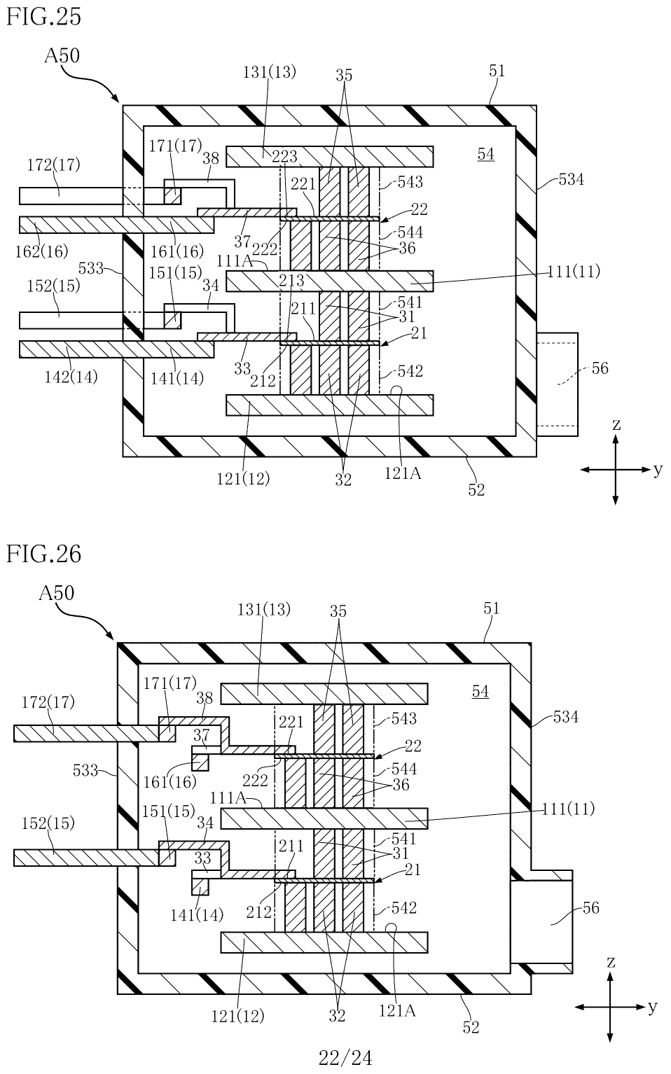

As shown in FIGS. 25 to 27, the hollow space 54 includes a third channel 543 and a fourth channel 544, in addition to the first channel 541 and the second channel 542. The third channel 543 is provided between the plurality of second semiconductor elements 22 and the third terminal 13 in the first direction z. The fourth channel 544 is provided between the plurality of second semiconductor elements 22 and the first terminal 11 in the first direction z. The first base 111 of the first terminal 11 is in contact with both the first channel 541 and the fourth channel 544.

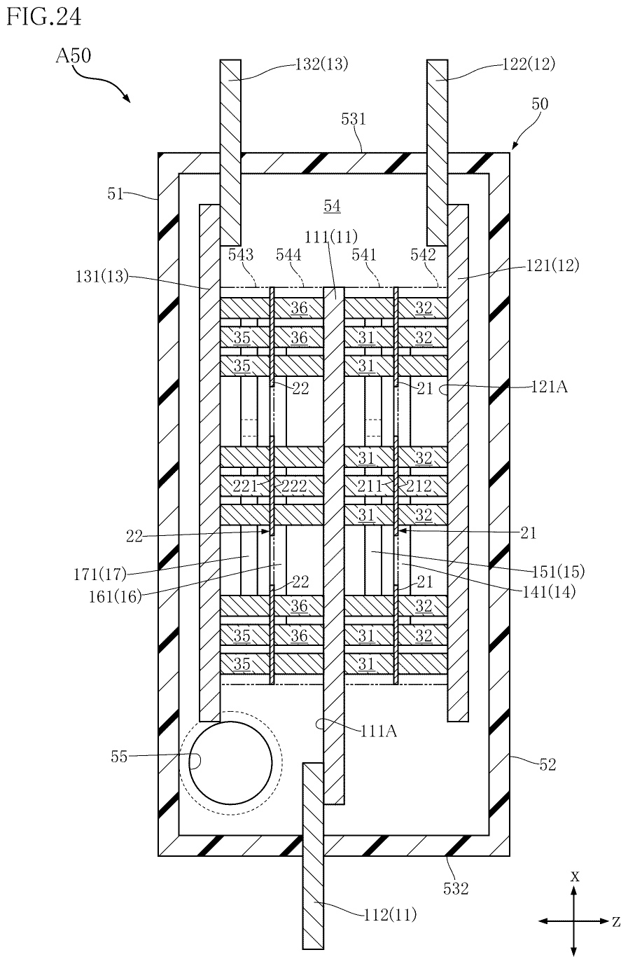

As shown in FIG. 24, the third terminal 13 is positioned opposite the second terminal 12 with respect to the first terminal 11 in the first direction z. In the semiconductor device A50, the third terminal 13 is positioned between the plurality of second semiconductor elements 22 and the top surface 51 of the housing 50 in the first direction z. The third terminal 13 is a metal plate containing copper, for example. The third terminal 13 has a third base 131 and a third extension 132. The third base 131 is contained in the hollow space 54 of the housing 50. The third base 131 is in contact with the third channel 543. The third base 131 has a band-like shape extending in the second direction x. The third extension 132 is electrically bonded to the end of the third base 131 on the first side in the second direction x. The third extension 132 is supported by the housing 50. The third extension 132 has a portion protruding outward from the first side surface 531 of the housing 50. As viewed in the first direction z, the third extension 132 overlaps the second extension 122 of the second terminal 12.

As shown in FIGS. 24 to 26, the second semiconductor elements 22 are positioned between the first base 111 of the first terminal 11 and the third base 131 of the third terminal 13 in the first direction z. The plurality of second semiconductor elements 22 are contained in the hollow space 54 of the housing 50. Each second semiconductor element 22 is in contact with both the third channel 543 and the fourth channel 544. As viewed in the first direction z, each second semiconductor element 22 overlaps the second mounting surface 111A of the first base 111. The second mounting surface 111A faces the same side as the first mounting surface 121A of the second base 121 of the second terminal 12 in the first direction z. The second semiconductor elements 22 are identical to the first semiconductor elements 21. Hence, the second semiconductor elements 22 are n-channel, vertical MOSFETs. The second semiconductor elements 22 are aligned in the second direction x.

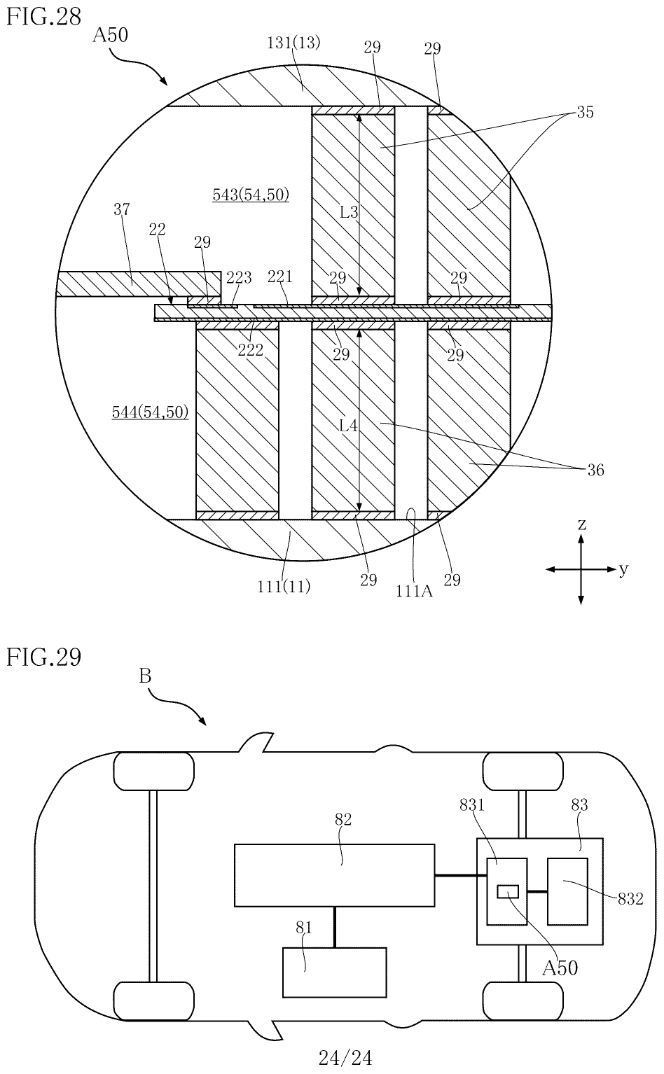

As shown in FIG. 28, each second semiconductor element 22 includes a third electrode 221, a fourth electrode 222, and a second gate electrode 223.

As shown in FIG. 28, the third electrode 221 is disposed on the side that faces the third base 131 of the third terminal 13 in the first direction z. The third electrode 221 is electrically connected to the third terminal 13. The third electrode 221 carries the current corresponding to the power after conversion by the second semiconductor element 22. That is, the third electrode 221 corresponds to the source of the second semiconductor element 22. The third electrode 221 is in contact with the third channel 543.

As shown in FIG. 28, the fourth electrode 222 is disposed on the side that faces the first base 111 of the first terminal 11 in the first direction z. The fourth electrode 222 is electrically connected to the first terminal 11. The fourth electrode 222 carries the current corresponding to the power before conversion by the second semiconductor element 22. That is, the fourth electrode 222 corresponds to the drain of the second semiconductor element 22. The fourth electrode 222 is in contact with the fourth channel 544.

As shown in FIG. 28, the second gate electrode 223 is disposed on the same side as the third electrode 221 in the first direction z. The second gate electrode 223 is electrically connected to the third signal terminal 16. The second gate electrode 223 receives a gate voltage that drives the second semiconductor element 22. As viewed in the first direction z, the second gate electrode 223 has a smaller area than the third electrode 221.

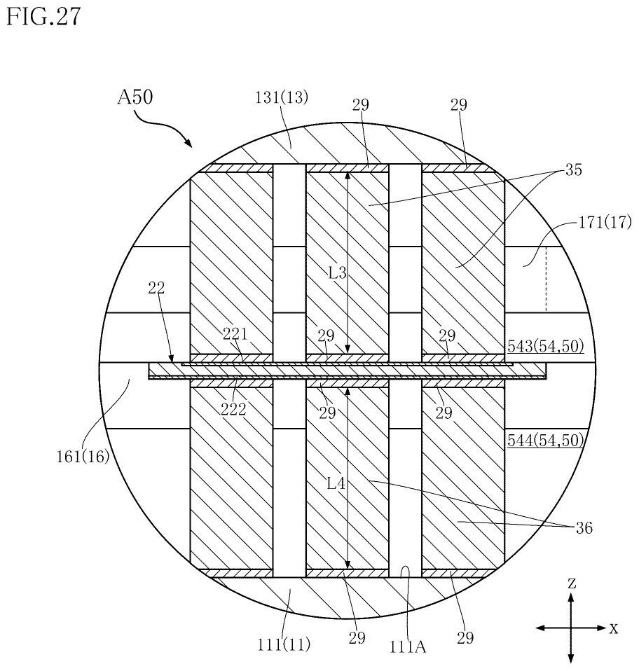

Each fifth conductive member 35 is electrically connected to the third electrode 221 of one of the second semiconductor elements 22 and to the third terminal 13. As shown in FIGS. 24 to 26, the fifth conductive members 35 are positioned between the plurality of second semiconductor elements 22 and the third base 131 of the third terminal 13 in the first direction z. The fifth conductive members 35 are contained in the third channel 543. The fifth conductive members 35 are metal pieces containing copper, for example. Each fifth conductive member 35 may have a cylindrical shape. Each fifth conductive member 35 is electrically connected at its end on the first side in the first direction z to the third electrode 221 of the corresponding second semiconductor element 22. Each fifth conductive member 35 is electrically connected at its end on the second side in the first direction z to the third base 131 of the third terminal 13. As shown in FIGS. 27 and 28, each fifth conductive member 35 has a dimension L3 in the first direction z, where the dimension L3 is greater than a dimension of the fifth conductive member 35 in a direction perpendicular to the first direction z.

Each sixth conductive member 36 is electrically connected to the fourth electrode 222 of one of the second semiconductor elements 22 and to the first terminal 11. As shown in FIGS. 24 to 26, the sixth conductive members 36 are positioned between the plurality of second semiconductor elements 22 and the first base 111 of the first terminal 11 in the first direction z. The sixth conductive members 36 are contained in the fourth channel 544. The sixth conductive members 36 are metal pieces containing copper, for example. Each sixth conductive member 36 may have a cylindrical shape. Each sixth conductive member 36 is electrically connected at its end on the first side in the first direction z to the fourth electrode 222 of the corresponding second semiconductor element 22. Each sixth conductive member 36 is electrically connected at its end on the second side in the first direction z to the second mounting surface 111A of the first base 111. As shown in FIGS. 27 and 28, each sixth conductive member 36 has a dimension L4 in the first direction z, where the dimension L4 is greater than a dimension of the sixth conductive member 36 in a direction perpendicular to the first direction z.

As shown in FIG. 23, the third signal terminal 16 is positioned on the first side in the third direction y from the third terminal 13. As viewed in the first direction z, the third signal terminal 16 overlaps the first signal terminal 14. The third signal terminal 16 is supported by the housing 50. The third signal terminal 16 is electrically connected to the second gate electrode 223 of each second semiconductor element 22. The third signal terminal 16 receives a gate voltage that drives the second semiconductor elements 22. The third signal terminal 16 is a metal lead containing copper, for example. As shown in FIG. 23, the third signal terminal 16 includes an inner portion 161 and an outer portion 162. The inner portion 161 is contained in the housing 50. The inner portion 161 has a portion contained in the hollow space 54 of the housing 50. The inner portion 161 has a portion extending in the second direction x. The outer portion 162 is connected to the inner portion 161. As shown in FIG. 25, the outer portion 162 protrudes outward from the third side surface 533 of the housing 50.

Each seventh conductive member 37 is electrically connected to the second gate electrode 223 of one of the second semiconductor elements 22 and to the fourth signal terminal 17. As shown in FIG. 23, each seventh conductive member 37 extends in the third direction y. Each seventh conductive member 37 has a portion contained in the third channel 543. The seventh conductive members 37 are metal leads containing copper, for example. Each seventh conductive member 37 is electrically connected at its end on the first side in the third direction y to the second gate electrode 223 of one of the second semiconductor elements 22 via a bonding layer 29. Each seventh conductive member 37 is electrically connected at its end on the second side in the third direction y to the inner portion 161 of the third signal terminal 16.

As shown in FIG. 23, the fourth signal terminal 17 is positioned on the same side as the third signal terminal 16 in the third direction y with respect to the third terminal 13. As viewed in the first direction z, the fourth signal terminal 17 overlaps the second signal terminal 15. The fourth signal terminal 17 is supported by the housing 50. The fourth signal terminal 17 is electrically connected to the third electrode 221 of each second semiconductor element 22. The fourth signal terminal 17 receives a voltage that is equal to the voltage applied to the third electrode 221 of each second semiconductor element 22. The fourth signal terminal 17 is a metal lead containing copper, for example. As shown in FIG. 23, the fourth signal terminal 17 includes an inner portion 171 and an outer portion 172. The inner portion 171 is contained in the housing 50. The inner portion 171 has a portion contained in the hollow space 54 of the housing 50. The inner portion 171 has a portion extending in the second direction x. As shown in FIGS. 25 and 26, the inner portion 171 is positioned closer to the top surface 51 of the housing 50 than the inner portion 161 of the third signal terminal 16 is. The outer portion 172 is connected to the inner portion 171. As shown in FIG. 26, the outer portion 172 protrudes outward from the third side surface 533 of the housing 50.

Each eighth conductive member 38 is electrically connected to the third electrode 221 of one of the second semiconductor elements 22 and to the fourth signal terminal 17. As shown in FIG. 23, each eighth conductive member 38 extends in the third direction y as viewed in the first direction z. As shown in FIG. 26, each eighth conductive member 38 spans over the inner portion 161 of the third signal terminal 16. Each eighth conductive member 38 has a portion contained in the third channel 543. The eighth conductive members 38 are metal leads containing copper, for example. Each eighth conductive member 38 is electrically connected at its end on the first side in the third direction y to the third electrode 221 of the corresponding second semiconductor element 22. Each eighth conductive member 38 is electrically connected at its end on the second side in the first direction z to the inner portion 171 of the fourth signal terminal 17.

With reference to FIG. 29, the following describes a vehicle B equipped with the semiconductor device A50. In one example, the vehicle B is an electric vehicle (EV).

As shown in FIG. 29, the vehicle B includes an on-board charger 81, a storage battery 82, and a drive system 83. The on-board charger 81 wirelessly receives power from an outdoor power supply facility (not shown). Alternatively, the on-board charger 81 may receive power via a wired connection. The on-board charger 81 includes a step-up DC-DC converter. The converter increases the voltage inputted to the on-board charger 81 and supplies the resulting power to the storage battery 82. The voltage is increased to 600 V, for example.

The drive system 83 propels the vehicle B. The drive system 83 includes an inverter 831 and a drive source 832. The semiconductor device A50 forms a part of the inverter 831. The power stored on the storage battery 82 is supplied to the inverter 831. The storage battery 82 supplies DC power to the inverter 831. Unlike the power system shown in FIG. 29, an additional step-up DC-DC converter may be provided between the storage battery 82 and the inverter 831. The inverter 831 converts the DC power to AC power. The inverter 831, including the semiconductor device A50, is electrically connected to the drive source 832. The drive source 832 includes an AC motor and a transmission. When AC power from the inverter 831 is supplied to the drive source 832, the AC motor rotates and transmits its rotation to the transmission. The transmission reduces the rotational speed transmitted from the AC motor as needed, and rotates the axle of the vehicle B. This causes the vehicle B to drive. While the vehicle B is being driven, the rotational speed of the AC motor needs to be adjusted based on relevant information, such as the position of the accelerator pedal. The inverter 831 of the semiconductor device A50 is used to adjust the frequency of the AC power to match the rotational speed of the AC motor as needed.

The following describes effects of the semiconductor device A50.

The semiconductor device A50 includes a first semiconductor element 21 and a first terminal 11. The first terminal 11 is positioned on a first side in a first direction z from the first semiconductor element 21 and is electrically connected to the first terminal 11. A first channel 541 is provided between the first semiconductor element 21 and the first terminal 11 in the first direction z. The first semiconductor element 21 is in contact with the first channel 541. This configuration of the semiconductor device A50 can further improve the cooling efficiency. Additionally, the semiconductor device A50 has a configuration in common with the semiconductor device A10, thereby achieving the same effects as the semiconductor device A10.

The present disclosure is not limited to the embodiments described above. Various design modifications may be made freely to the specific structure of the components according to the present disclosure.

The present disclosure includes embodiments described in the following clauses.

Clause 1.
a semiconductor device comprising:
a semiconductor element; and
a first terminal that is positioned on a first side in a first direction from the semiconductor element and electrically connected to the semiconductor element,
wherein a first channel is provided between the semiconductor element and the first terminal in the first direction, and
the semiconductor element is in contact with the first channel.

Clause 2.

The semiconductor device according to Clause 1, further comprising a first conductive member electrically connected to the semiconductor element and the first terminal,
wherein the first conductive member is contained in the first channel.

Clause 3.

The semiconductor device according to Clause 2, wherein the semiconductor element includes a first electrode that faces the first channel, and
the first conductive member is electrically connected to each of the first electrode and the first terminal.

Clause 4.

The semiconductor device according to Clause 3, wherein the first electrode is in contact with the first channel.

Clause 5.

The semiconductor device according to Clause 4, wherein the first conductive member includes a first member and a second member that are spaced apart from each other in a direction perpendicular to the first direction.

Clause 6.

The semiconductor device according to Clause 5, wherein a dimension of the first conductive member in the first direction is greater than a dimension of the first conductive member in a direction perpendicular to the first direction.

Clause 7.

The semiconductor device according to Clause 3, further comprising a second terminal positioned on a side opposite the first terminal with respect to the semiconductor element in the first direction,
wherein the semiconductor element includes a second electrode that faces the second terminal, and
the second electrode is electrically connected to the second terminal.

Clause 8.

The semiconductor device according to Clause 7, further comprising a second conductive member electrically connected to each of the second electrode and the second terminal,
wherein a second channel is provided between the semiconductor element and the second terminal in the first direction and contains the second conductive member, and
the semiconductor element is in contact with the second channel.

Clause 9.

The semiconductor device according to Clause 8, wherein the second electrode is in contact with the second channel.

Clause 10.

The semiconductor device according to Clause 9, wherein a dimension of the second conductive member in the first direction is greater than a dimension of the second conductive member in a direction perpendicular to the first direction.

Clause 11.

The semiconductor device according to Clause 8, wherein the first conductive member includes a first peripheral surface facing in a direction perpendicular to the first direction,
the second conductive member includes a second peripheral surface facing in a direction perpendicular to the first direction, and
an area of the second peripheral surface is greater than an area of the first peripheral surface.

Clause 12.

The semiconductor device according to Clause 7, wherein the second electrode is electrically bonded to the second terminal.

Clause 13.

The semiconductor device according to any one of Clauses 7 to 12, further comprising a signal terminal,
wherein the semiconductor element includes a gate electrode positioned on a same side as the first electrode in the first direction, and
the signal terminal is electrically connected to the gate electrode.

Clause 14.

The semiconductor device according to Clause 13, further comprising a third conductive member electrically connected to each of the gate electrode and the signal terminal,
wherein a portion of the third conductive member is contained in the first channel.

Clause 15.

The semiconductor device according to Clause 13, further comprising a housing that supports each of the first terminal, the second terminal, and the signal terminal,
wherein the housing includes a hollow space that includes the first channel, and
the semiconductor element is contained in the hollow space.

Clause 16.

The semiconductor device according to Clause 15, wherein the housing includes an inlet and an outlet each of which leads into the hollow space, and
the inlet and the outlet are positioned opposite each other in a direction perpendicular to the first direction with respect to the first conductive member.

Clause 17.

A vehicle comprising:
a drive source; and
the semiconductor device according to Clause 13,
wherein the semiconductor device is electrically connected to the drive source.

### REFERENCE NUMERALS

A10 to A50: semiconductor device B: vehicle 11: first terminal 111: first base 111A: second mounting surface 112: first extension 12: second terminal 121: second base 121A: first mounting surface 122: second extension 13: third terminal 131: third base 132: third extension 14: first signal terminal 141: inner portion 142: outer portion 15: second signal terminal 151: inner portion 152: outer portion 16: third signal terminal 161: inner portion 162: outer portion 17: fourth signal terminal 171: inner portion 172: outer portion 21: first semiconductor element 211: first electrode 212: second electrode 213: first gate electrode 22: second semiconductor element 221: third electrode 222: fourth electrode 223: second gate electrode 29: bonding layer 31: first conductive member 31A: first peripheral surface 32: second conductive member 32A: second peripheral surface 33: third conductive member 34: fourth conductive member 35: fifth conductive member 36: sixth conductive member

37: seventh conductive member 38: eighth conductive member 50: housing 51: top surface 52: bottom surface 531 to 534: first to fourth side surfaces 54: hollow space 541 to 544: first to fourth channels 55: inlet 56: outlet 60: coolant 81: on-board charger 82: storage battery 83: drive system 831: inverter 832: drive source z: first direction x: second direction y: third direction

1. A semiconductor device comprising:
a semiconductor element; and
a first terminal that is positioned on a first side in a first direction from the semiconductor element and electrically connected to the semiconductor element,
wherein a first channel is provided between the semiconductor element and the first terminal in the first direction, and
the semiconductor element is in contact with the first channel.

2. The semiconductor device according to claim 1, further comprising a first conductive member electrically connected to the semiconductor element and the first terminal,
wherein the first conductive member is contained in the first channel.

3. The semiconductor device according to claim 2, wherein the semiconductor element includes a first electrode that faces the first channel, and
the first conductive member is electrically connected to each of the first electrode and the first terminal.

4. The semiconductor device according to claim 3, wherein the first electrode is in contact with the first channel.

5. The semiconductor device according to claim 4, wherein the first conductive member includes a first member and a second member that are spaced apart from each other in a direction perpendicular to the first direction.

6. The semiconductor device according to claim 5, wherein a dimension of the first conductive member in the first direction is greater than a dimension of the first conductive member in a direction perpendicular to the first direction.

7. The semiconductor device according to claim 3, further comprising a second terminal positioned on a side opposite the first terminal with respect to the semiconductor element in the first direction,
wherein the semiconductor element includes a second electrode that faces the second terminal, and
the second electrode is electrically connected to the second terminal.

8. The semiconductor device according to claim 7, further comprising a second conductive member electrically connected to each of the second electrode and the second terminal,
wherein a second channel is provided between the semiconductor element and the second terminal in the first direction and contains the second conductive member, and
the semiconductor element is in contact with the second channel.

9. The semiconductor device according to claim 8, wherein the second electrode is in contact with the second channel.

10. The semiconductor device according to claim 9, wherein a dimension of the second conductive member in the first direction is greater than a dimension of the second conductive member in a direction perpendicular to the first direction.

11. The semiconductor device according to claim 8, wherein the first conductive member includes a first peripheral surface facing in a direction perpendicular to the first direction,
the second conductive member includes a second peripheral surface facing in a direction perpendicular to the first direction, and
an area of the second peripheral surface is greater than an area of the first peripheral surface.

12. The semiconductor device according to claim 7, wherein the second electrode is electrically bonded to the second terminal.

13. The semiconductor device according to claim 7, further comprising a signal terminal,
wherein the semiconductor element includes a gate electrode positioned on a same side as the first electrode in the first direction, and
the signal terminal is electrically connected to the gate electrode.

14. The semiconductor device according to claim 13, further comprising a third conductive member electrically connected to each of the gate electrode and the signal terminal,
wherein a portion of the third conductive member is contained in the first channel.

15. The semiconductor device according to claim 13, further comprising a housing that supports each of the first terminal, the second terminal, and the signal terminal,
wherein the housing includes a hollow space that includes the first channel, and
the semiconductor element is contained in the hollow space.

16. The semiconductor device according to claim 15, wherein the housing includes an inlet and an outlet each of which leads into the hollow space, and
the inlet and the outlet are positioned opposite each other in a direction perpendicular to the first direction with respect to the first conductive member.

17. A vehicle comprising:
a drive source; and
the semiconductor device according to claim 13,
wherein the semiconductor device is electrically connected to the drive source.
